(19) United States
(12) Patent Application Publication
(10) Pub. No.: US 2025/0300044 A1
(43) Pub. Date: Sep. 25, 2025

(54) POWER SEMICONDUCTOR MODULE

(71) Applicant: Semikron Danfoss GmbH, Flensburg (DE)

(72) Inventors: Nauman ul Haque, Munich (DE); Johann Asam, Adelzhausen (DE); Thomas Zoels, Hebertshausen (DE)

(21) Appl. No.: 19/086,312

(22) Filed: Mar. 21, 2025

(30) Foreign Application Priority Data
Mar. 22, 2024 (DE) 102024108239.9

(51) Int. Cl. H01L 23/495; G01R 19/00; H01L 25/07

(52) U.S. Cl. CPC H01L 23/49562; H01L 23/49548; H01L 25/072; G01R 19/0092

(57) ABSTRACT

A power semiconductor module including a substrate, a terminal, and a conducting track. The conducting track includes a narrow region between the terminal and a power semiconductor in order to provide for an easy implementation of an electric current sensor.

### CROSS-REFERENCE TO RELATED APPLICATION

This application claims foreign priority benefits under 35 U.S.C. § 119 to German Patent Application No. 102024108239.9 filed on Mar. 22, 2024, the content of which is hereby incorporated by reference in its entirety.

### TECHNICAL FIELD

The invention relates to a power semiconductor module.

### BACKGROUND

Power semiconductor modules are used in many applications, where a consumer of electric energy like an electric motor or a heating element should be provided with electric power. It is typically required to measure an electric current that flows through a terminal of the power semiconductor module.

### SUMMARY

It is an object of the invention to provide for a power semiconductor module that is embodied alternatively or better compared with existing solutions, especially with an improved solution in order to mount a current sensor. This is achieved by a power semiconductor module according to claim 1. Preferred embodiments can be derived from the dependent claims.

The invention relates to a power semiconductor module. The power semiconductor module comprises at least a substrate, a terminal, a conducting track, and a power semiconductor. The conducting track at least partially covers a side of the substrate. The conducting track at least electrically connects the power semiconductor to the terminal. The conducting track comprises a narrow region between the power semiconductor and the terminal in which a lateral extension of the conducting track transverse to a current flow path between the power semiconductor and the terminal is smaller compared to one neighboring region or both neighboring regions along the current flow path. The module is preferably adapted to mount an electric current sensor above the substrate and/or over the narrow region of the conducting track. The measurement principle of the current sensor is typically based on magnetic field measurements.

With such a power semiconductor module, a narrow region in a conducting track can be provided, above which a current sensor can be mounted. The narrow region provides for an increased current density and thus for a higher field strength of a magnetic field at the current sensor. The narrow region also concentrates the flowing current, so that it is ensured that the entire current is measured.

The module may also be adapted to mount the electric current sensor above the narrow region.

A power semiconductor module can especially be a module having a power semiconductor, or at least being adapted in order to carry a power semiconductor. The power semiconductor is typically an entity that controls electric current for an electric consumer like a motor or an electric heater. The power semiconductor typically controls voltages and/or currents which typically have values above voltages or currents used in pure logic communication. The substrate may typically be embodied as a base and may typically be made of a non-conducting material, for example a plastic or ceramic material, typically covered with a structured conducting material. The terminal may especially be made of a conducting material like copper or aluminum or another metal or conductive material, and may especially either be a bulk object or an exposed area on the substrate being used for connecting the power semiconductor module with an electric consumer or another entity. Typically, the terminal is adapted to carry large currents, which are consumed by the electric consumer. The conducting track is typically also made of an electrically conducting material like copper or aluminum or another metal and is typically also adapted to carry the current for the electric consumer. The conducting track is typically embodied as a sheet on the substrate.

The power semiconductor may be a part of the power semiconductor module. Alternatively, there may be a designated place on the power semiconductor module where a power semiconductor can be provided. It is connected with the conducting track to the terminal. Mounting the current sensor above the conducting track may especially mean mounting it opposite to the substrate with respect to the conducting track.

The lateral extension is measured transverse to a current flow path. This lateral extension is typically taken in a direction parallel to the substrate. The current flow path can be easily determined in a specific implementation, because the current flows along the conducting track. Alternatively, it can be said that the current flow path is defined along an extension of the conducting track. It can also be said alternatively that the lateral extension is measured along a longitudinal extension of the conducting track from the power semiconductor to the terminal at a specific point. The lateral extension is not to be confused with a thickness of the conducting track. Typically, the conducting track has a constant thickness, wherein it can also be provided that different thicknesses can be used. Typically, the lateral extension is larger, especially much larger, than the thickness of the conducting track.

Along the flow path, it is possible to define different regions. According to the implementation described herein, there is a narrow region with a smaller lateral extension compared to one or both neighboring regions. This can especially be seen when looking on the power semiconductor module in a top view. The power semiconductor module is adapted to mount an electric current sensor above the narrow region of the conducting track. This can, for example, be embodied as further described below by providing a cutout in a cover layer. There can also be additional means for securing a current sensor, for example soldering posts or clip connectors.

For example, the electric current sensor may have a dimension of 13×6.5×1.5 mm. Two of these dimensions can be used in order to define the extension of the narrow region when seen from above. The dimensions can also be scaled, for example from 0.3× to 5×. Such scaled dimensions can also be used in order to specify the extension of the narrow region.

Especially, the substrate may extend in a plane. The conducting track typically also extends in a plane. These two planes may be parallel to each other. The positioning of the electric current sensor above the substrate and/or above the narrow region especially means that there is a distance between the current sensor and the substrate and/or the narrow region. For example, if the substrate extends horizontally, positioning the current sensor above the substrate means that the substrate is positioned in a specific vertical high above the substrate. Positioning the electric current sensor over the narrow region especially means that the narrow region of the conducting track is arranged between the substrate and the electric current sensor.

Especially, the power semiconductor module may further comprise a cover layer fully or partially covering this conducting track on a side opposed to the substrate, wherein the cover layer may especially be adapted to secure the electric current sensor above the narrow region. Such a cover layer may especially be made of an electrically non-conducting material, for example plastic. It can protect the conducting track and other components against involuntary electrical connections. Especially, a cutout may be formed in the cover layer above the narrow region to place the electric current sensor in the cutout. Such a cutout is a defined space where an electric current sensor can be placed. For example, the power semiconductor module can be delivered to a customer without the electric current sensor, but with the cutout already being formed in the cover layer. Then, the electric current sensor can be inserted by the customer. Alternatively, the current sensor can be permanently mounted, e.g. glued, in the cutout and supplied to the customer as a single unit with the power module.

It may be provided that the cutout is arranged fully over material of the conducting track. This means especially that there is no hole or cutout in the conducting track. This ensures a proper measurement.

Especially, it may be provided that the conducting track or each conducting track extends in only one plane on the substrate. This means that there is no second plane of conducting tracks in the power semiconductor module. Especially, it may be provided that there is no overlap between different conducting tracks.

Especially, it may be provided that the conducting track always fully covers the substrate along a direction perpendicular to the current flow path. This is typically valid along an extension of the conducting track perpendicular to the current flow path. Especially, there may be no spilt, cutout, or hole in the conducting path. This may ensure a smooth current flow.

According to an implementation, the power semiconductor module comprises only one terminal being electrically connected to the conducting track. This allows a connection using the only terminal. For example, the conducting track may extend along a straight line between the power semiconductor and the terminal.

According to an implementation, the power semiconductor module comprises a further terminal, especially in addition to the terminal already mentioned. The further terminal may be electrically connected to the power semiconductor and the terminal by the conducting track. This allows, for example, connecting two electric consumers, wherein each of the electric consumers may be connected to a separate terminal. In such a case, the conducting track may split at a point to connect both terminals with the power semiconductor.

Especially, a further current flow path between the power semiconductor and the further terminal and the current flow path between the power semiconductor and the terminal may overlap at least at the narrow region. This allows for a measurement of both currents flowing through the respective terminals integrally with only one current sensor.

According to an implementation, the conducting track may have a widened region between the narrow region and the terminal, wherein the widened region may be connected to the narrow region with a connecting track. According to an implementation, the conducting track may have a further widened region between the narrow region and the further terminal, wherein the further widened region is connected to the narrow region with a further connecting track.

Especially, the widened region may have, seen parallel to a longitudinal extension of the narrow region, a constant extension between the connecting track and the terminal. Especially, the further widened region may have, seen in parallel to a longitudinal extension of the narrow region, a constant extension between the further connecting track and the further terminal.

Using such widened regions, it may be provided for a specifically lower resistance between the narrow region and the terminals. In a top view, this may be seen as an L-shape.

A longitudinal extension may especially represent the longest extension of the narrow region. The narrow region may have, especially in a top view, the shape of a rectangle.

According to an implementation, the conducting track may comprise a connecting region connecting an end of the narrow region opposite to the power semiconductor with the terminal, wherein the end of the narrow region may be closer to an edge of the module than a portion at which the connecting region contacts the terminal. According to an implementation, the conducting track may comprise a further connecting region connecting an end of the narrow region opposite to the power semiconductor with the further terminal, wherein the end of the narrow region is closer to an edge of the module than a portion at which the further connecting region contacts the further terminal.

Such an implementation may look like an S-shape in a top view. It may provide for a specifically tailored magnetic field at the current sensor.

The connecting region may have, at least in straight parts, a constant cross-section transverse to the current flow path. The further connecting region may have, at least in straight parts, a constant cross-section transverse to the further current flow path. This allows for a specific buildup of a magnetic field and for a constant current flow.

The connecting region may have at least one straight part oriented parallel to a longitudinal extension of the narrow region and being positioned between the narrow region and the terminal. The further connecting region may have at least one straight part oriented parallel to a longitudinal extension of the narrow region and being positioned between the narrow region and the further terminal. Such straight parts may especially provide for an additional magnetic field at the narrow region and thus also at a position of the current sensor.

The narrow region may be positioned between the terminal and the further terminal. For example, there may be a symmetrical arrangement of the conducting track, especially such that the narrow region defines a mirror line.

Especially, the terminal may have a constant cross-section transverse to a current flow direction in the terminal. Especially, the further terminal may have a constant cross-section transverse to a current flow direction in the terminal. This may especially be the case in a respective part of the respective terminal, or it may be the case in the entire terminal.

The conducting track may be embodied as a planar sheet on the substrate. Especially, it may have a constant thickness, wherein such a thickness is typically measured perpendicular to the substrate. The substrate may especially be embodied as a plate, especially of a constant thickness, which may especially correspond to a plane.

According to an implementation, the terminal and/or the further terminal is embodied as a bulk connecting element, especially extending partially over the substrate. Such a terminal can especially be used in order to connect to an external consumer of electric power.

According to an implementation, the terminal and/or the further terminal is embodied as an exposed area on the substrate. Especially, it may be an exposed area of conducting material. It can be used in order to connect other entities like external power consumers or power consumers embedded in the module. For example, an exposed area may not be covered by molding material. However, it may alternatively also be covered.

It should especially be noted that the electric current sensor is mounted above the conducting track and thus also above the substrate. The electric current sensor is typically not mounted above a terminal. This may especially lead to a higher integration and a more compact module.

The cover layer as mentioned above can especially be molded. It should be noted that all techniques for molding can be used. Using a cutout as described above or any other connection with a molded cover layer can lead to a very precise placement of the electric current sensor, because a molding process can be performed with very tight tolerances. No extra space is required for current sensor placement.

The power semiconductor module may also comprise an electric current sensor. It may be positioned above the substrate and/or over the narrow region of the conducting track. With regard to positioning of the electric current sensor, all embodiments disclosed herein can be applied.

The current sensor may especially be a coreless current sensor, that is a sensor without a magnetic core. This may be a more compact sensor compared with a current sensor comprising a core.

The cutout in the cover layer may especially be etched, may be milled, or may be provided already when molding the cover layer. The electric current sensor can especially be connected by using a flex layer. This can bring electrical signals out of the sensor. Alternatively, other typical connection techniques such as press-fit pins or solder pins can also be used.

### BRIEF DESCRIPTION OF THE DRAWINGS

Further details will be apparent from the described embodiments that are given with respect to the accompanying drawings, wherein:

FIG. 1 shows a power semiconductor module in a sectional view,

FIG. 2 shows the same power semiconductor module in another sectional view,

FIG. 3 shows a part of a power semiconductor module according to a first embodiment,

FIG. 4 shows a part of a power semiconductor module according to a second embodiment,

FIG. 5 shows a part of a power semiconductor module according to a third embodiment,

FIG. 6 shows a cross-sectional view of a power semiconductor module, and

FIG. 7 shows a cross-sectional view of another power semiconductor module.

It should be noted that the designs, especially of the conducting track, shown in the figures, may be of inventive significance.

### DETAILED DESCRIPTION

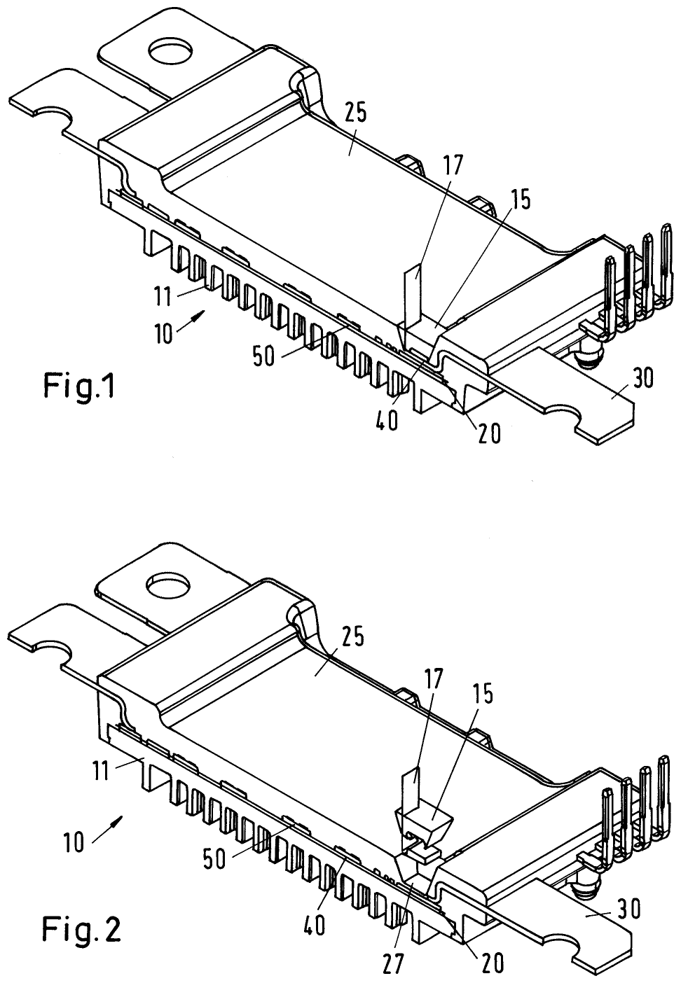

FIG. 1 shows a power semiconductor module 10 according to an embodiment in a first embodiment in a sectional view. The power semiconductor module 10 comprises a substrate 20, which comprises a non-electrically conducting layer such as a ceramic or a plastic material. The substrate 20 is provided on a cooling element 11, which is placed on the lower part of the power semiconductor module 10. The power semiconductor module 10 comprises a terminal 30. The terminal 30 is connected with a conducting track 40 with a power semiconductor 50. The power semiconductor 50 can be used in order to control power consumption of an electric consumer. The terminal 30 can be used to connect this electric consumer with the power semiconductor module 10. The conducting track electrically connects the power semiconductor 50 with the terminal 30.

The power semiconductor module 10 is covered by a cover layer 25. The cover layer 25 is made of a non-conducting plastic material. It can especially be applied by molding. In the cover layer 25, there is placed an electric current sensor 15 with a connector 17 to read out data. The electric current sensor 15 is used in order to measure a current flowing through the conducting track 40. This is described further below.

FIG. 2 shows the same power semiconductor module 10 as FIG. 1 in a cross-sectional view, wherein the electric current sensor 15 is lifted out of its place. There it is seen that in the cover layer 25, there is provided a cutout 27, which is used to place the electric current sensor 15 in it and to secure it at a very specific place.

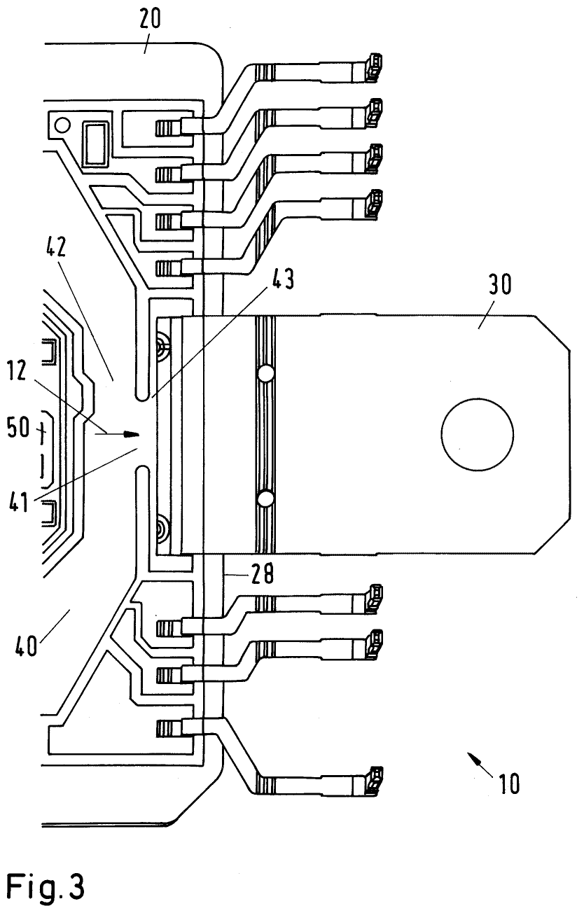

FIG. 3 shows a top view on the power semiconductor module 10 with the cover layer 25 and the electric current sensor 15 being removed. It is thus a top view directly on the substrate 20, the terminal 30, and the conducting track 40.

When electric current flows from the power semiconductor 50 to the terminal 30, it flows along a current flow path 12, which is shown in FIG. 3 with an arrow. This can also be regarded as an integral over vectors defining a current flow at a specific place, wherein the current flow path 12 is horizontal in FIG. 3 because the conducting track 14 is embodied mirror-symmetrically with respect to a horizontal imaginary line that can be defined by the arrow defining the current flow path 12 in FIG. 3. This imaginary line solely serves as a mirror line. Due to this configuration, the current flowing in the conducting track 14 does not see a structure that would deviate its straight flow, even if the lateral dimension changes.

The conducting track 40 comprises a narrow region 41, where a lateral extension seen transverse to the current flow path 12 is smaller compared with a first neighboring region 42 and a second neighboring region 43 when seen along the current flow path 12. The first neighboring region 42 connects the narrow region 41 with the power semiconductor 50. The second neighboring region 43 connects the narrow region 41 with the terminal 30. Both neighboring regions 42, 43 have a larger lateral extension compared with the narrow region 41. This concentrates the current at the narrow region 41, leading to a higher current density. The electric current sensor 15 is placed just above the narrow region 41 in order to measure the specifically high magnetic field, created by the current flowing through the narrow region 41.

As seen in FIG. 3, the terminal 30 is fixed near an edge 28 of substrate 20. Typically, the edge 28 of the substrate 20 is near and parallel to an edge of the module 10, which is not shown in FIG. 3

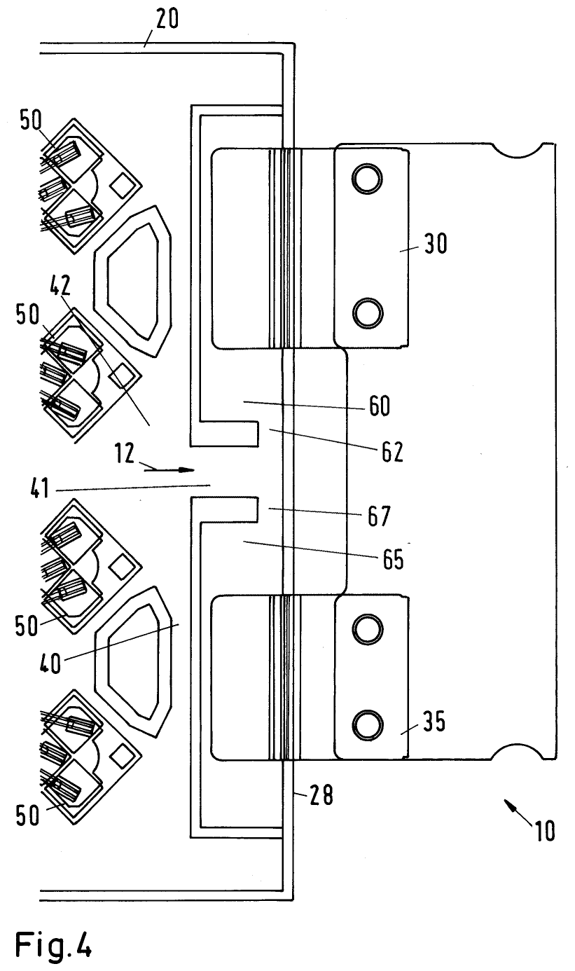

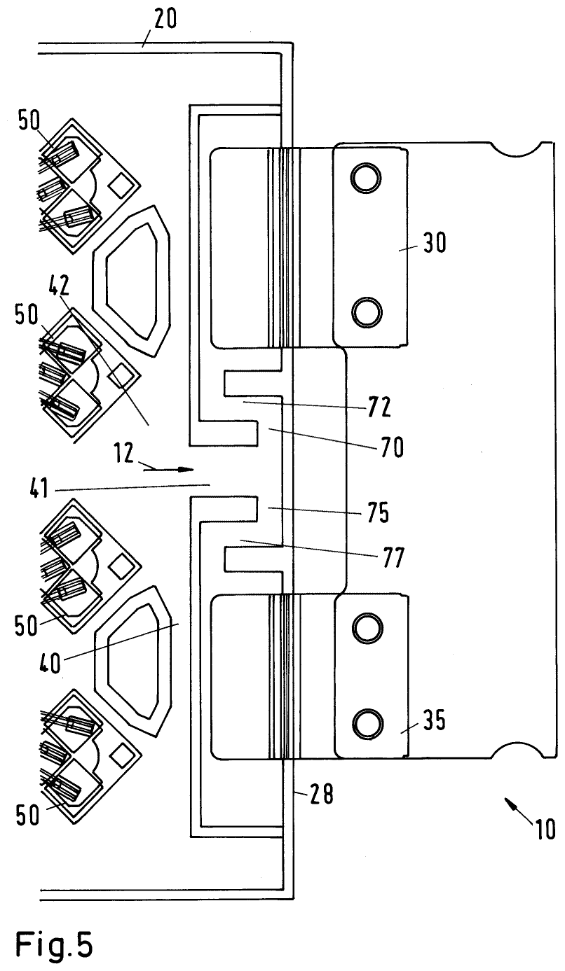

FIG. 4 shows a part of a power semiconductor module 10 according to a second embodiment. The views of FIGS. 4 and 5 are in principle identical to the view of FIG. 3.

In contrast to the first embodiment, the power semiconductor module 10 according to the second embodiment has not only the terminal 30, but also a further terminal 35. In order to connect both terminals 30, 35, the conducting track 40 comprises a widened region 60 and a further widened region 65. These widened regions are positioned between the narrow region 41 and the respective terminal 30, 35. The widened region 60 is connected with the narrow region 41 by a connecting track 62. The further widened region 65 is connected with the narrow region 41 with a further connecting track 67. In top view, the respective widened region 60, 65 and its connecting track 62, 67 has approximately an L-shape. This allows for a very low resistance between the connecting track 62, 67 and the respective terminal 30, 35. However, the straight line of current flow in the narrow region 41 is preserved, while at the same time provided for a very compact design.

As seen in FIG. 4, the narrow region 41 as an extension in the direction of the current flow path 12, which is horizontal in FIG. 4, that is much longer compared with the first embodiment. In this direction, which is horizontal in FIG. 4, it has its longitudinal extension.

FIG. 5 shows a power semiconductor module 10 according to a third embodiment. In contrast to the second embodiment, the conducting track 40 comprises between the narrow region 41 and the terminal 30 a connecting region 70. Likewise, it comprises a further connecting region 75 between the narrow region 41 and the further terminal 35. The connecting region 70 and the further connecting region 75 are embodied with a constant cross-section transverse to the respective current flow path, at least outside of corner regions. The connecting region 70 comprises a straight part 72, which is oriented in parallel to the current flow path and the extension of the narrow region 41. Likewise, the further connecting region 75 comprises a further straight part 77, which is also parallel to the narrow region 41. This allows for a superposition of magnetic fields generated by current flowing in the narrow region 41, and the two straight parts 72, 77, which is measured by a current sensor.

The design of the connecting regions 70, 75 as shown in FIG. 5 approximately corresponds to an S-shaped design. This can be used to electrically connect the terminals 30, 35 further away from the edge 28 of the substrate 20 than an end of the narrow region 41. This design saves space.

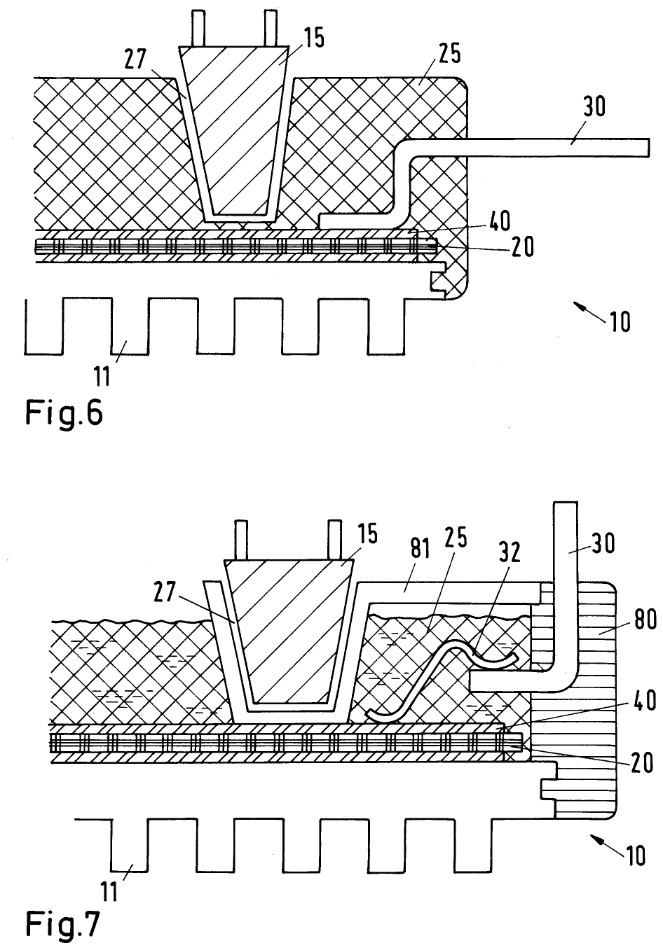

FIG. 6 shows a part of a power semiconductor module 10, which is not specifically according to one of the shown embodiments of FIGS. 1 to 5, but which illustrates an implementation of the connection of the terminal 30 that can be applied for all shown embodiments and for other implementations. The same is true for FIG. 7. In the implantation shown in FIG. 6, the terminal 30 is attached to the track 40 and the module is encased in a molded cover layer 25. The sensor 15 is placed in the cutout 27 in this molding.

In the implementation shown in FIG. 5, the terminal 30 extends parallel to the substrate 20. It is connected directly to the conducting track 40 by an S-shaped portion.

FIG. 7 shows an alternative implementation. There, the terminal 30 extends vertically upwards in a direction perpendicular to the substrate 20. The terminal 30 is embedded in a non-conducting frame 80 of the power module 10. The cover layer 25 in this embodiment may, for example, be a soft gel filling or an epoxy material. The sensor 15 is supported by a sensor support 81 in which a cutout 27 enables the positioning of the sensor 15 correctly above the conducting track 40. It has an end extending in the cover layer 25 and is connected to the conducting track 40 with a wire bond 32.

With the shown implementations, a simple and reliable current measurement can be performed using the electric current sensor 15, which can be placed at a suitable position and can be precisely secured.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A power semiconductor, comprising
a substrate,
a terminal,
a conducting track, and
a power semiconductor,
wherein the conducting track at least partially covers a side of the substrate,
wherein the conducting track at least electrically connects the power semiconductor to the terminal,
wherein the conducting track comprises a narrow region between the power semiconductor and the terminal in which a lateral extension of the conducting track transverse to a current flow path between the power semiconductor and the terminal is smaller compared to one neighboring region or both neighboring regions along the current flow path, and
wherein the module is adapted to mount an electric current sensor above the substrate over the narrow region of the conducting track.

2. The power semiconductor module according to claim 1,
further comprising a cover layer fully or partially covering the conducting track on a side opposed to the substrate, wherein the cover layer is adapted to secure the electric current sensor above the narrow region.

3. The power semiconductor module according to claim 2,
wherein a cutout is formed in the cover layer above the narrow region to place the electric current sensor in the cutout.

4. The power semiconductor module according to claim 3,
wherein the cutout is arranged fully over material of the conducting track.

5. The power semiconductor module according to claim 1,
wherein the conducting track or each conducting track extends in only one plane on the substrate.

6. The power semiconductor module according to claim 1,
wherein the conducting track always fully covers the substrate along a direction perpendicular to the current flow path.

7. The power semiconductor module according to claim 1,
wherein the power semiconductor module comprises only one terminal being electrically connected by the conducting track.

8. The power semiconductor module according to claim 1,
wherein the power semiconductor module further comprises a further terminal,
wherein the further terminal is electrically connected to the power semiconductor and to the terminal by the conducting track.

9. The power semiconductor module according to claim 8,
wherein a further current flow path between the power semiconductor and the further terminal and the current flow path between the power semiconductor and the terminal overlap at least at the narrow region.

10. The power semiconductor module according to claim 8,
wherein the conducting track has a widened region between the narrow region and the terminal, wherein the widened region is connected to the narrow region with a connecting track,
and/or
wherein the conducting track has a further widened region between the narrow region and the further terminal, wherein the further widened region is connected to the narrow region with a further connecting track.

11. The power semiconductor module according to claim 10,
wherein the widened region has, seen parallel to a longitudinal extension of the narrow region, a constant extension between the connecting track and the terminal,
and/or
wherein the further widened region has, seen parallel to a longitudinal extension of the narrow region, a constant extension between the further connecting track and the further terminal.

12. The power semiconductor module according to claim 8,
wherein the conducting track comprises a connecting region connecting an end of the narrow region opposite to the power semiconductor with the terminal, wherein the end of the narrow region is closer to an edge of the module than a portion at which the connecting region contacts the terminal,
and/or
wherein the conducting track comprises a further connecting region connecting an end of the narrow region opposite to the power semiconductor with the further terminal, wherein the end of the narrow region is closer to an edge of the module than a portion at which the further connecting region contacts the further terminal.

13. The power semiconductor module according to claim 12,
wherein the connecting region has, at least in straight parts, a constant cross section transverse to the current flow path,
and/or
wherein the further connecting region has, at least in straight parts, a constant cross section transverse to the further current flow path.

14. The power semiconductor module according to claim 13,
wherein the connecting region has at least one straight part oriented parallel to a longitudinal extension of the narrow region and being positioned between the narrow region and the terminal,
and/or
wherein the further connecting region has at least one straight part oriented parallel to a longitudinal extension of the narrow region and being positioned between the narrow region and the further terminal.

15. The power semiconductor module according to claim 8,
wherein the narrow region is positioned between the terminal and the further terminal.

16. The power semiconductor module according to claim 1,
wherein the terminal has a constant cross section transverse to a current flow direction in the terminal,
and/or
wherein the further terminal has a constant cross section transverse to a current flow direction in the further terminal.

17. The power semiconductor module according to claim 1,
wherein the conducting track is embodied as a planar sheet on the substrate.

18. The power semiconductor module according to claim 1,
wherein the terminal and/or the further terminal is embodied as a bulk connecting element extending partially over the substrate.

19. The power semiconductor module according to claim 1,
wherein the terminal and/or the further terminal is embodied as an exposed area on the substrate.

20. The power semiconductor module according to claim 1,
further comprising an electric current sensor being positioned above the substrate and over the narrow region of the conducting track.
